(19) United States
(12) Patent Application Publication
(10) Pub. No.: US 2012/0042942 A1
(43) Pub. Date: Feb. 23, 2012

(54) SOLAR CELL HAVING A BUFFER LAYER WITH LOW LIGHT LOSS

(76) Inventors: Sang-Cheol PARK, Seoul (KR); Jung-Gyu NAM, Suwon-si (KR); Su-Jin KIM, Seoul (KR); Mutsumi SUGIYAMA, Noda-shi (JP)

(21) Appl. No.: 13/167,652

(22) Filed: Jun. 23, 2011

(30) Foreign Application Priority Data
Aug. 23, 2010 (KR) 10-2010-0081547

(51) Int. Cl. H01L 31/0224; H01L 31/0232; H01L 31/0264

(52) U.S. Cl. 136/256; 136/262; 136/264; 136/265

(57) ABSTRACT

Provided is a solar cell that includes: a substrate; a first electrode disposed on the substrate; a light absorbing layer disposed on the first electrode; a buffer layer disposed on the light absorbing layer; and a second electrode disposed on the buffer layer, wherein the buffer layer contains a compound represented by one of the following Formulas 1 and 2:

(In₁₋ₓGaₓ)₂O₃ Formula 1

(In₁₋ₓAlₓ)₂O₃ Formula 2

wherein x is 0<x<1.

### CROSS-REFERENCE TO RELATED APPLICATION

This application claims priority to and the benefit of Korean Patent Application No. 10-2010-0081547 filed in the Korean Intellectual Property Office on Aug. 23, 2010, the entire content of which is incorporated herein by reference.

### BACKGROUND OF THE INVENTION

(a) Field of the Invention

The present invention relates to a solar cell.

(b) Description of the Related Art

A solar cell is an apparatus that converts solar cell energy into electrical energy using photoelectric effect.

Solar energy is clean energy or next-generation energy that will possibly replace fuel energy and atomic energy. Given that fuel energy causes greenhouse effect due to a discharge of CO₂ and atomic energy contributes to global pollution by generating radioactive wastes, solar energy is an attractive option as an alternative energy source.

A solar cell generates electricity using a P-type semiconductor and an N-type semiconductor and is classified into various types according to the material used as a light absorbing layer.

A typical solar cell structure includes a front window layer (transparent conductive layer), a PN layer, and a rear electrode layer that are sequentially deposited on a substrate.

When sunlight is incident on the solar cell having the above structure, electrons collect in an N layer and holes collect in a P layer, thereby generating current.

A compound solar cell (for example: CIGS compound solar cell) converts sunlight into electrical energy at high efficiency without using silicon, unlike the silicon-based solar cells. A compound solar cell may be manufactured by depositing elements such as copper (Cu), indium (In), gallium (Ga), and selenium (Se) or/and S on an electrode formed on a glass substrate and/or a flexible substrate such as one made of stainless steel, Titanium etc.

In the CIGS compound solar cell, the CIGS layer used as the p-type semiconductor and the ZnO:Al layer used as the n-type semiconductor may form the p-n junction. Cadmium sulfide (CdS), or other compounds having a bandgap that is between the bandgaps of the above two materials or higher than the bandgaps of the above two materials, may be used as the buffer layer to form a good junction between the p-type semiconductor and the n-type semiconductor.

However, a buffer layer made of cadmium sulfide, etc., causes light loss in a short wavelength region, thereby degrading light efficiency.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention provides a solar cell with improved light transmittance and efficiency.

In one aspect, the present invention provides a solar cell that includes: a substrate; a first electrode disposed on the substrate; a light absorbing layer disposed on the first electrode; a buffer layer disposed on the light absorbing layer, and a second electrode disposed on the buffer layer, wherein the buffer layer contains a compound represented by one of the following Formulas 1 and 2:

(In₁₋ₓGaₓ)₂O₃ Formula 1

(In₁₋ₓAlₓ)₂O₃ Formula 2

where x is 0<x<1.

The light absorbing layer may be made of at least one selected from a group of CdTe, CuInSe₂, Cu(In,Ga)Se₂, Cu(In,Ga)(Se,S)₂, Ag(InGa)Se₂, Cu(In,Al)Se₂, and CuGaSe₂.

The first electrode may be made of a reflective conductive metal.

The first electrode may be made of one of molybdenum (Mo), copper (Cu), and aluminum (Al).

The second electrode may be made of a transparent conductive oxide.

The second electrode may be made of ITO, IZO, ZnO, GaZO, ZnMgO, and SnO2.

The solar cell may further include an anti-reflective layer disposed on the second electrode.

In another aspect, the present invention provides a solar cell that includes: a substrate; a first electrode disposed on the substrate; a light absorbing layer disposed on the first electrode; a buffer layer disposed on the light absorbing layer; and a second electrode disposed on the buffer layer, wherein the buffer layer contains. indium oxide (In₂O₃) doped with at least one of silicon (Si) and tin (Sn).

The light absorbing layer may be made of at least one of CdTe, CuInSe₂, Cu(In,Ga)Se₂, Cu(In,Ga)(Se,S)₂, Ag(InGa)Se₂, Cu(In,Al)Se₂, and CuGaSe₂.

The first electrode may be made of a reflective conductive metal.

The first electrode may be made of one of molybdenum (Mo), copper (Cu), and aluminum (Al).

The second electrode may be made of a transparent conductive oxide.

The second electrode may be made of ITO, IZO, ZnO, GaZO (Gallium zinc oxide), ZnMgO, and SnO₂.

The solar cell may further include an anti-reflective layer disposed on the second electrode.

In another aspect, the invention is a solar cell having a buffer layer between a p-type semiconductor layer and an n-type semiconductor layer, wherein the buffer layer contains a compound represented by one of the following Formulas 1 and 2:

(In₁₋ₓGaₓ)₂O₃ Formula 1

(In₁₋ₓAlₓ)₂O₃ Formula 2

where x is 0<x<1.

According to the exemplary embodiment of the present invention, it is possible to reduce light loss in a short wavelength region by using a buffer layer of a new composition, thereby improving light efficiency.

### BRIEF DESCRIPTION OF THE DRAWINGS

FIG. 1 is a schematic cross-sectional view showing a solar cell according an exemplary embodiment of the present invention;

FIG. 2 is a graph showing EQE (External Quantum Efficiency) according to a wavelength when a thickness of a buffer layer made of cadmium sulfide (CdS) is changed;

FIGS. 3 and 4 are graphs showing light transmittance according to a wavelength when a material of a buffer layer is changed;

FIG. 5 is a graph showing bandgaps at different levels of gallium content in a buffer layer according to an exemplary embodiment of the present invention;

FIG. 6 is a graph showing bandgaps at different levels of aluminum content in a buffer layer according to an exemplary embodiment of the present invention;

FIG. 7 is a graph showing bandgaps of an In₂O₃ buffer layer with and without silicon (Si) added, according to another exemplary embodiment of the present invention; and

FIG. 8 shows a graph showing bandgaps of an In₂O₃ buffer layer with and without tin (Sn) added, according to another exemplary embodiment of the present invention.

### DETAILED DESCRIPTION OF THE EMBODIMENTS

The present invention will be described more fully hereinafter with reference to the accompanying drawings, in which exemplary embodiments of the invention are shown.

As those skilled in the art would realize, the described embodiments may be modified in various different ways without departing from the spirit or scope of the present invention.

The exemplary embodiments that are disclosed herein are provided in order to sufficiently transmit the spirit of the present invention to a person of an ordinary skill in the art.

The size and thickness of layers and regions may be exaggerated for better comprehension and ease of description in the drawings.

In addition, in the case of when the layer is mentioned to be present “on” the other layer or substrate, it may be directly formed on the other layer or substrate or a third layer may be interposed between them.

Like reference numerals designate like components throughout the specification.

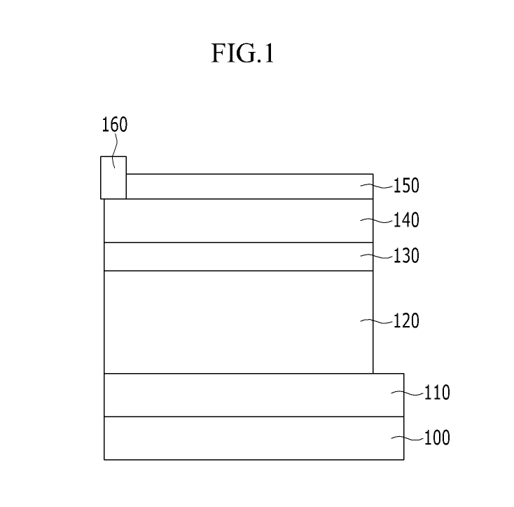

FIG. 1 is a schematic cross-sectional view showing a solar cell according to an exemplary embodiment of the present invention.

Referring to FIG. 1, a solar cell according to an exemplary embodiment of the present invention includes a substrate 100, a first electrode 110 disposed on the substrate 100, a light absorbing layer 120 disposed on the first electrode 110, a buffer layer 130 disposed on the light absorbing layer 120, a second electrode 140 disposed on the buffer layer 130, an anti-reflective layer 150 disposed on the second electrode 140, and a grid electrode 160. The anti-reflective layer 150 may be omitted.

The first electrode 110 may be made of a conductive metal, such as molybdenum (Mo), copper (Cu), aluminum (Al).
The light absorbing layer 120 may include at least one of an element selected from I-group of the periodic table, an element selected from III-group of the periodic table and an element selected from VI-group of the periodic table.
The light absorbing layer 120 may be made of a compound semiconductor such as CdTe, CuInSe₂, Cu(In,Ga)Se₂, Cu(In,Ga)(Se,S)₂, Ag(InGa)Se₂, Cu(In,Al)Se₂, and CuGaSe₂.

The buffer layer 130 is formed between the P-type semiconductor layer 120 and the N-type semiconductor layer 140 that form the pn junction and serves to relieve the lattice constant and the difference of the energy bandgap between the p-type semiconductor and the n-type semiconductor.

Therefore, the energy bandgap value of the material that is used as the buffer layer 130 may be a bandgap value between the bandgap values of the N-type semiconductor and the P-type semiconductor or higher than the bandgap values of the N-type semiconductor and the P-type semiconductor.

The buffer layer 130 according to the exemplary embodiment of the present invention may be made of a compound represented by Formula 1 or Formula 2 below:

(In₁₋ₓGaₓ)₂O₃ Formula 1

(In₁₋ₓAlₓ)₂O₃ Formula 2

where x is 0<x<1.

The buffer layer 130 according to another exemplary embodiment of the present invention may be formed by doping indium oxide (In₂O₃) with at least one of silicon (Si), tin (Sn), nitrogen (N). Resistance rate or carrier density may be controlled by doping the buffer layer 130 with at least one of silicon (Si), tin (Sn), nitrogen (N).

The buffer layer 130 according to the exemplary embodiment of the present invention may be made of a compound represented by Formula 3 or Formula 4 below:

(In₁₋ₓSix)₂O₃ Formula 3

(In₁₋ₓSnₓ)₂O₃ Formula 4

(In₁₋ₓNₓ)₂O₃ Formula 5

where x is 0<x<1.

The buffer layer 130 may be formed using a spin coating method, a dipping method, a chemical bath deposition (CBD), or Atomic Layer Deposition (ALD) or the like.

The second electrode 140 may be made of transparent conductive oxide. The second electrode 140 may be made of ITO, IZO, ZnO, GaZO, ZnMgO or SnO₂.

When light is incident on the light absorbing layer 120 through the first electrode 110 or the second electrode 140, electrons and holes are generated and electrons move to the first electrode 110 and holes move to the second electrode 140, such that current flows.

Alternatively, electrons move to the second electrode 140 and holes move to the first electrode 110, according to a type of the light absorbing layer, such that current may flow.

As the light absorbance of the light absorbing layer 120 is increased, the light efficiency of the solar cell may be increased.

The anti-reflective layer 150 may be made of fluoro magnesium MgF₂ and the grid electrode 160 may be made of Silver or Silver paste (Ag) or aluminum (Al) or nickel aluminum alloy, or the like.

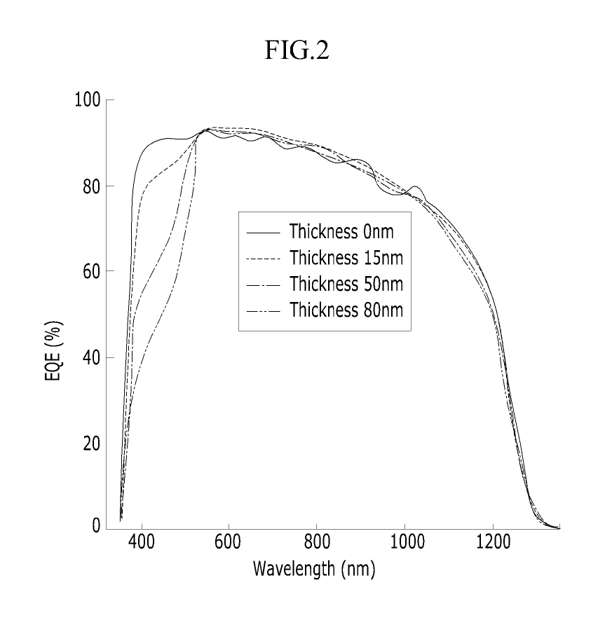

FIG. 2 is a graph showing EQE (External Quantum Efficiency) as a function of wavelength for buffer layers made of cadmium sulfide CdS at different thicknesses.

Referring to FIG. 2, when the buffer layer is made of cadmium sulfide (CdS), the transmittance decreases as the thickness increases when the wavelength is 500 nm or less. Therefore, light loss may occur at a wavelength of 500 nm or less.

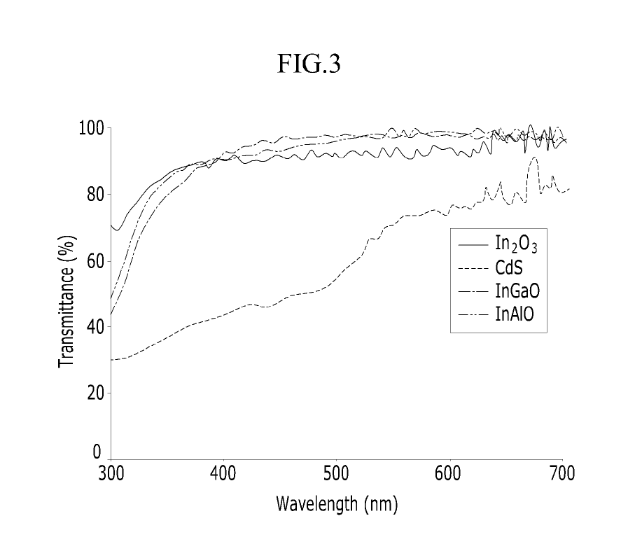

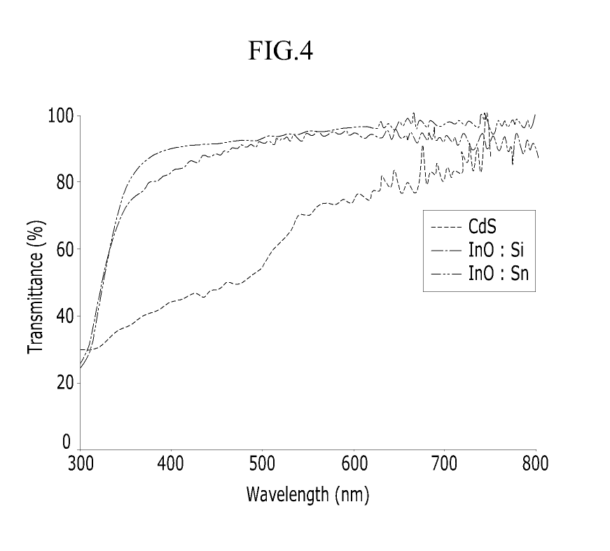

FIGS. 3 and 4 are graphs showing light transmittance according to a wavelength when the buffer layer contains different materials.

FIG. 3 shows light transmittance when cadmium sulfide (CdS), indium oxide (In₂O₃), InGaO, and InAlO are used as the buffer layer.

In particular, InGaO was measured in the case where x is 0.1 at (In₁₋ₓGaₓ)₂O₃ and InAlO was measured in the case where x is 0.34 at (In₁₋ₓAlₓ)₂O₃.

According to FIG. 3, light transmittance at the short wavelength region of 500 nm or less is better with a buffer layer that includes indium oxide (In₂O₃) mixed with gallium or aluminum, than with a buffer layer that is made of cadmium sulfide (CdS).

FIG. 4 shows light transmittances of buffer layers with different compositions: indium oxide doped with silicon (InO:Si), cadmium sulfide (CdS), and indium oxide doped with tin (InO:Sn).

In particular, the indium oxide doped with silicon (InO:Si) was measured in the case where 0.14 atomic % of Si was added to In₂O₃ and the indium oxide doped with tin (InO:Sn) was measured in the case where 0.15 atomic % of Sn is added to In₂O₃.

As shown in FIG. 4, the transmittance at the short wavelength region of 500 nm or less is better with a buffer layer that contains indium oxide doped with silicon (InO:Si) or indium oxide doped with tin (InO:Sn) according to another exemplary embodiment of the present invention than with a buffer layer made of cadmium sulfide (CdS).

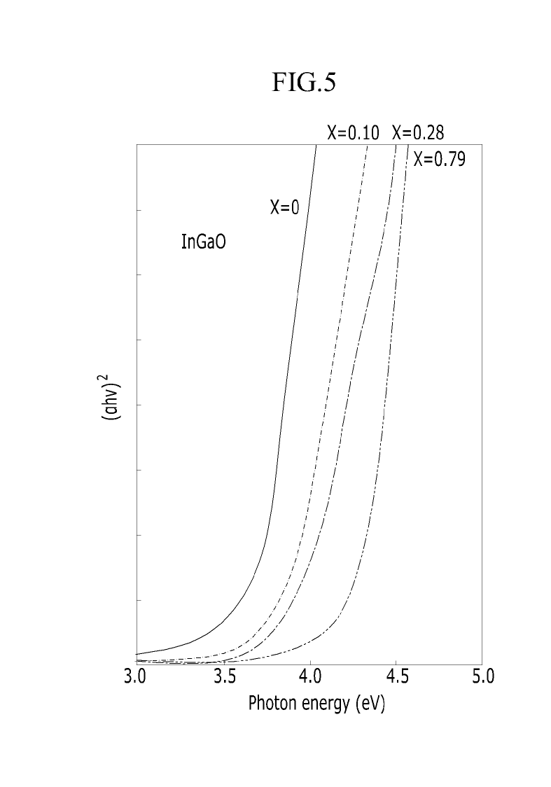

FIG. 5 is a graph showing bandgaps at different levels of gallium content in a buffer layer according to an exemplary embodiment of the present invention.

In detail, the bandgap is measured with a UV/Vis Spectrometer for a buffer layer made of (In₁₋ₓGaₓ)₂O₃ when x is 0, 0.10, 0.28, and 0.79. The bandgaps are shown as a value (αhν)² according to photon energy.

It can be appreciated that the bandgap (Eg) is represented by the following Equation.

αhν=A(hν−Eg)n

where A is a constant, α is optical absorption coefficient, hν is photon energy, n is a value according to an energy shift.

In a direct shift semiconductor, it is known that n=½.

The bandgap value is approximately at the value on the horizontal axis at the point where an extended linear region of the plot intersects the horizontal axis when the linear region extends toward the horizontal axis in FIG. 5.

Referring to FIG. 5, when x is 0, bandgap is 3.65 eV; when x is 0.1, bandgap is 3.85 eV; when x is 0.28, bandgap is 3.9 eV, and when x is 0.79, bandgap is about 4.3 Ev.

That is, as the amount of gallium (Ga) added to indium oxide increases, the value of the bandgap increases.

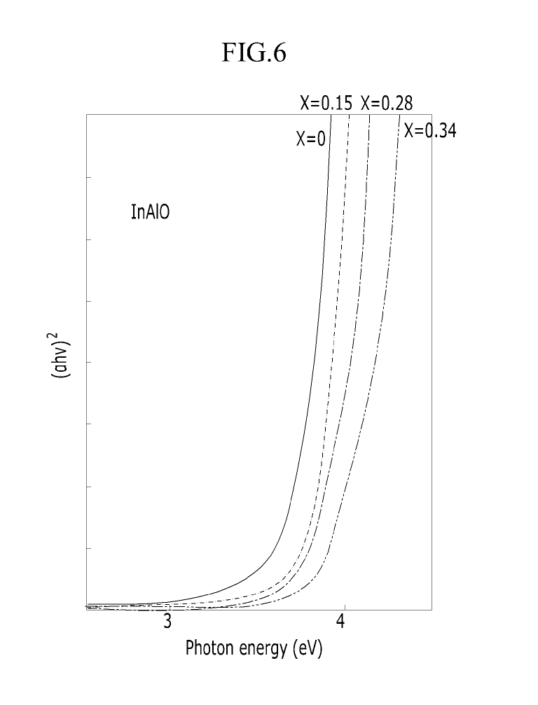

FIG. 6 is a graph showing bandgaps at different levels of aluminum content in a buffer layer according to an exemplary embodiment of the present invention.

In detail, in Formula (In₁₋ₓAlₓ)₂O₃, when x is 0, 0.15, 0.28, and 0.34, the results measured with the UV/Vis Spectrometer are shown a value of (αhν)2 according to the photon energy.

Referring to FIG. 6, bandgap is about 3.65 eV when x is 0, about 3.85 eV when x is 0.15, about 3.9 eV when x is 0.28, and about 4.3 eV when x is 0.34.

That is, as the amount of aluminum (Al) added to indium oxide as an alloy increases, the bandgap also increases.

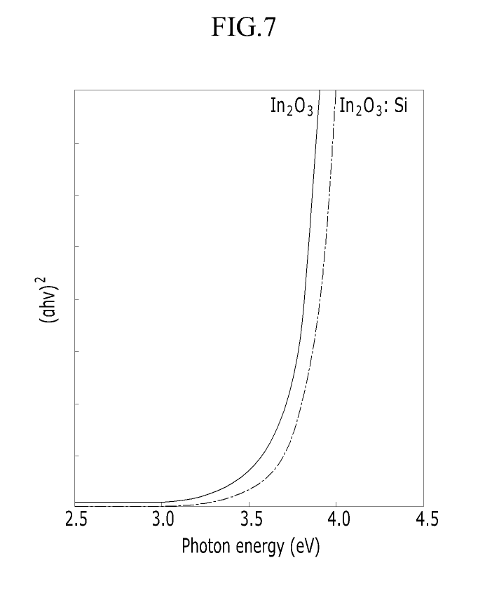

FIG. 7 is a graph showing bandgaps of an In₂O₃ buffer layer with and without silicon (Si), according to another exemplary embodiment of the present invention.

In more detail, in the case of adding 0.15 atomic % of silicon (Si) to the indium oxide (In₂O₃) as impurity, the results measured with the UV/Vis Spectrometer is shown as the value of (αhν)² according to the photon energy.

As shown in FIG. 7, the bandgap of indium oxide (InO:Si) with silicon (Si) added as impurity in the buffer layer according to the exemplary embodiment of the present invention is 3.67 eV and has a larger bandgap than the indium oxide (In₂O₃) without the silicon added.

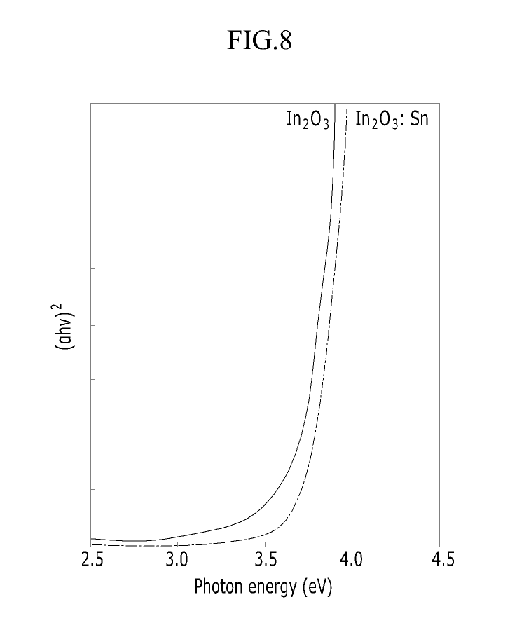

FIG. 8 is a graph showing a bandgap according to the content of tin (Sn) in a buffer layer according to another exemplary embodiment of the present invention.

In detail, when 0.14 atomic % of tin (Sn) is added to the indium oxide (In₂O₃) as impurity, the results measured with the UV/Vis Spectrometer are shown as the (αhν)₂ according to the photon energy.

Referring to FIG. 8, the bandgap of indium oxide (InO:Sn) with silicon (Sn) added as impurity in the buffer layer according to the exemplary embodiment of the present invention is about 3.70 eV. This is a larger bandgap than in the case of indium oxide (In₂O₃) without tin added.

As such, the desired bandgap can be controlled by alloying gallium (Ga) or aluminum (Al) that is the same III-group as indium (In) with indium oxide (In₂O₃) in the buffer layer according to the exemplary embodiment of the present invention and the resistance rate and the carrier density can be controlled by adding silicon (Si) or tin (Sn) to indium oxide (In₂O₃).

Therefore, the present invention can increase the light efficiency by minimizing the light loss in the short wavelength region.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

<Description of symbols>

| | | | |
|---|---|---|---|
| 100 | Substrate | 110 | First electrode |
| 120 | Light absorbing layer | 130 | Buffer layer |
| 140 | Second electrode | 150 | Anti-reflective layer |
| 160 | Grid electrode | | |

What is claimed is:

1. A solar cell, comprising:
a substrate;
a first electrode disposed on the substrate;
a light absorbing layer disposed on the first electrode;
a buffer layer disposed on the light absorbing layer; and
a second electrode disposed on the buffer layer,
wherein the buffer layer contains a compound represented by one of the following Formulas 1 and 2:
(In₁₋ₓGaₓ)2O3 Formula 1
(In₁₋ₓAlₓ)2O3 Formula 2
where x is 0<x<1.

2. The solar cell of claim 1, wherein:
the light absorbing layer is made of at least one compound selected from a group of CdTe, CuInSe₂, Cu(In,Ga)Se₂, Cu(In,Ga)(Se,S)₂, Ag(InGa)Se₂, Cu(In,Al)Se₂, and CuGaSe₂.

3. The solar cell of claim 2, wherein:
The first electrode is made of a conductive metal.

4. The solar cell of claim 3, wherein:
the first electrode is made of one of molybdenum (Mo), copper (Cu), and aluminum (Al).

5. The solar cell of claim 4, wherein:
the second electrode is made of a transparent conductive oxide.

6. The solar cell of claim 5, wherein:
the second electrode is made of ITO, IZO, ZnO, GaZO, ZnMgO, and SnO₂.

7. The solar cell of claim 1, further comprising
an anti-reflective layer disposed on the second electrode.

8. A solar cell, comprising:
a substrate;
a first electrode disposed on the substrate;
a light absorbing layer disposed on the first electrode;
a buffer layer disposed on the light absorbing layer; and
a second electrode disposed on the buffer layer,
wherein the buffer layer contains indium oxide (In₂O₃) doped with at least one of silicon (Si) and tin (Sn).

9. The solar cell of claim 8, wherein:
the light absorbing layer is made of at least one compound selected from a group consisting of CdTe, CuInSe₂, Cu(In,Ga)Se₂, Cu(In,Ga)(Se,S)₂, Ag(InGa)Se₂, Cu(In,Al)Se₂, and CuGaSe₂.

10. The solar cell of claim 9, wherein:
the first electrode is made of a reflective conductive metal.

11. The solar cell of claim 10, wherein:
the first electrode is made of one of molybdenum (Mo), copper (Cu), and aluminum (Al).

12. The solar cell of claim 11, wherein:
the second electrode is made of a transparent conductive oxide.

13. The solar cell of claim 12, wherein:
the second electrode is made of ITO, IZO, ZnO, GaZO, ZnMgO, and SnO₂.

14. The solar cell of claim 8, further comprising:
an anti-reflective layer disposed on the second electrode.

15. A solar cell comprising:
a p-type semiconductor layer;
an n-type semiconductor layer;
a buffer layer between the p-type semiconductor layer and the n-type semiconductor layer, wherein the buffer layer contains a compound represented by one of the following Formulas 1 and 2:
(In₁₋ₓGaₓ)₂O₃ Formula 1
(In₁₋ₓAlₓ)₂O₃ Formula 2
where x is 0<x<1.
